(19) United States
(12) Patent Application Publication
(10) Pub. No.: US 2007/0131937 A1
(43) Pub. Date: Jun. 14, 2007

(54) Display device and method of manufacturing thereof

(75) Inventor: Joon-Hak Oh, Yongin-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co.,Ltd.

(21) Appl. No.: 11/592,526

(22) Filed: Nov. 3, 2006

(30) Foreign Application Priority Data
Dec. 12, 2005 (KR) 10-2005-0121600

(51) Int. Cl. H01L 29/04; H01L 29/08

(52) U.S. Cl. 257/72; 257/40; 257/59; 257/103; 977/950; 977/952

(57) ABSTRACT

According to an embodiment of the present invention, a display device includes a substrate, at least one nano-emitting body disposed on the substrate where each nano-emitting body includes at least one shell and has a coaxial structure, at least one light source disposed on at least one of a lower and an upper part of the substrate to provide the at least one nano-emitting body with light, and at least one switching element disposed on the substrate and configured to turn the at least one light source on and off.

### CROSS-REFERENCE TO RELATED APPLICATION

This application claims priority to and the benefit of Patent Application No. 10-2005-0121600 filed in the Korean Intellectual Property Office, Republic of Korea, on Dec. 12, 2005, the entire content of which is incorporated by reference.

### BACKGROUND OF THE INVENTION

(a) Field of the Invention

The present invention relates to a display device and a manufacturing method thereof.

(b) Description of the Related Art

Display devices visually provide text and graphical information in a manner that may be viewed by a user, where display devices may include cathode ray tubes (CRTs), liquid crystal displays (LCDs), electroluminescence devices, and photoluminescence devices. Cathode ray tubes display information by causing an electron beam from an electron gun to collide with a phosphor surface of a screen to generate light emission. Liquid crystal displays apply a voltage to field generating electrodes, which generate an electric field on a liquid crystal layer that determine the directional orientation of liquid crystal molecules in the liquid crystal layer, and thereby control transmittance of light passing through the liquid crystal layer. Electroluminescence devices form excitons by combining electrons inserted from one electrode and holes inserted from another electrode at an emission layer. The excitons are emitted to generate energy. Photoluminescence devices absorb energy from externally provided light to develop an excited state. When the devices change from the excited state to a ground state, the absorbed energy is emitted as light. Such display devices have a plurality of pixels. Each pixel is of a micro-size such that the devices achieve high resolution. Since a pixel is patterned by photolithography, there is a limitation for forming a micro-sized pixel.

The above information disclosed in this Background section is only for enhancement of understanding of the background of the invention and therefore it may contain information that does not form the prior art that is already known in this country to a person of ordinary skill in the art.

### SUMMARY OF THE INVENTION

One or more embodiments of the present invention are made in an effort to solve the above problems and others, and to provide a display device having high resolution by forming a nano-sized pixel. According to one exemplary embodiment of the present invention, a display device includes a substrate, at least one nano-emitting body disposed on the substrate where each nano-emitting body includes at least one shell and has a coaxial structure, at least one light source disposed on at least one of a lower and an upper part of the substrate and configured to provide the at least one nano-emitting body with light, and at least one switching element disposed on the substrate and configured to turn the at least one light source on and off.

A plurality of switching elements may include a plurality of thin film transistors arranged on a pixel. A plurality of light sources may be operatively connected to the plurality of thin film transistors. A plurality of switching elements may be arranged in a matrix. The at least one nano-emitting body may include a luminescent organic semiconductor. The shell may include a light transmission material where the light transmission material comprises at least one of rhodamine-B, fluorescein, pyrene, pentacene, rubrene, polypyrrole, polyaniline, and polythiophene. The at least one nano-emitting body may further include a core and at least one shell surrounding the core. One of the core and the at least one shell may include a luminescent organic semiconductor. The shell may include a light transmission material where the light transmission material comprises at least one of rhodamine-B, fluorescein, pyrene, pentacene, rubrene, polypyrrole, polyaniline, and polythiophene. At least one of the core and the at least one shell may include a light transmission material. The light transmission material may comprise an insulating material. The light transmission material may comprise at least one of polymethylmethacrylate, polystyrene, polydivinylbenzene, polyacrylonitrile, and polycarbonate. The at least one nano-emitting body may further include a first shell, a core formed inside the first shell, and a second shell formed between the first shell and the core and having a luminescent organic semiconductor where at least one of the core and the first shell may have a light transmission material. The light transmission material may include rhodamine-B, fluorescein, pyrene, pentacene, rubrene, polypyrrole, polyaniline, or polythiophene. The light transmission material may include an insulating material. The light transmission material may include one of polymethylmethacrylate, polystyrene, polydivinylbenzene, polyacrylonitrile, and polycarbonate. The at least one nano-emitting body may include one of a nanowire and a nanotube. The at least one nano-emitting body may include a coaxial structure which is one of raised and laid.

According to another exemplary embodiment of the present invention, a method for manufacturing a display device includes preparing at least one nano-emitting body, disposing the prepared at least one nano-emitting body on a substrate, and disposing at least one light source on one of a lower and an upper part of the substrate where the at least one light source is configured to provide the disposed at least one nano-emitting body with light.

The preparation of the at least one nano-emitting body may include preparing a template having a pore, and supplying one of an organic and an inorganic material in the pore through a vapor phase method. The one of an organic or an inorganic material may be supplied to the pore through by vapor deposition. The one of an organic and an inorganic material may be supplied to the pore with through vapor polymerization. The vapor polymerization may include supplying vapor monomers in the pores, and polymerizing the supplied monomers. The supplied monomers may be polymerized under a vacuum. The monomers may include one of methylmethacrylate, styrene, divinylbenzene, vinylphenoL pyrrole, aniline, thiophene, pentacene, and rubrene. The monomers may be polymerized at a temperature of about 50° C. to about 200° C. The method may further include supplying a polymerization initiator to the pores before supplying the monomers in the pores. The polymerization initiator may include at least one of 2,2′-azobisisobutyronitrile, benzoyl peroxide, cerium ammonium nitride, and FeCl₃. The method may further include separating at least one nano-emitting body from the template after polymerizing the monomers. The template may include aluminum oxide, and the at least one nano-emitting body may be separated from the template by etching the template. The etching may be performed by using at least one of hydrochloric acid and sodium hydroxide.

At least one nano-emitting body may be prepared by preparing a template having a pore, inserting a first material in the pore and forming a first shell of a tube shape having a hollowed inside, and inserting a second material in the pores and forming a core inside of the first shell. Preparing the at least one nano-emitting body may further include inserting a third material in the pore to form a second shell having a tube shape inside of the first shell, after forming the first shell. At least one of the first shell, the second shell, and the core may be formed by one of vapor deposition and vapor polymerization. At least one of the first material, the second material, and the third material may include a luminescent organic semiconductor.

The scope of the present invention is defined by the claims, which are incorporated into this section by reference. A more complete understanding of embodiments of the present invention will be afforded to those skilled in the art, as well as a realization of additional advantages thereof, by a consideration of the following detailed description. Reference will be made to the appended sheets of drawings that will first be described briefly.

### BRIEF DESCRIPTION OF THE DRAWINGS

FIG. 1 is a schematic diagram of a display device according to an exemplary embodiment of the present invention.

FIG. 2 is a schematic diagram of a display device according to another exemplary embodiment of the present invention.

FIG. 3 is an enlarged view of an ‘A’ portion of the display device shown in FIG. 1 and FIG. 2.

FIG. 4A to FIG. 4C are schematic diagrams showing many different types of nano-emitting bodies.

FIG. 5A to FIG. 5F are schematic diagrams sequentially showing a method for manufacturing a nano-emitting body according to an exemplary embodiment of the present invention.

FIG. 6 and FIG. 7 are schematic diagrams of a thin film transistor array panel having a plurality of pixels Ps, respectively.

FIG. 8 is a layout view of an enlarged pixel of the thin film transistor array panel shown in FIG. 6 and FIG. 7.

FIG. 9 and FIG. 10 are cross-sectional views of the thin film transistor array panel shown in FIG. 8, taken along lines IX-IX and X-X, respectively.

Embodiments of the present invention and their advantages are best understood by referring to the detailed description that follows. It should be appreciated that like reference numerals are used to identify like elements illustrated in one or more of the figures.

### DETAILED DESCRIPTION OF THE EMBODIMENTS

The present invention will be described more fully hereinafter with reference to the accompanying drawings, in which preferred embodiments of the invention are shown. As those skilled in the art would realize, the described embodiments may be modified in various different ways, all without departing from the spirit or scope of the present invention. In the drawings, the thickness of layers, films, panels, regions, etc., may be exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. It will be further understood that terms such as above, below, upper, lower, right, left, front, back, and other terms are intended to indicate the relative position of elements, and are not considered limiting. For example, a system including a first element disposed above a second element in a first orientation may also be described as having the second element above the first element if the system is turned upside down in a second orientation.

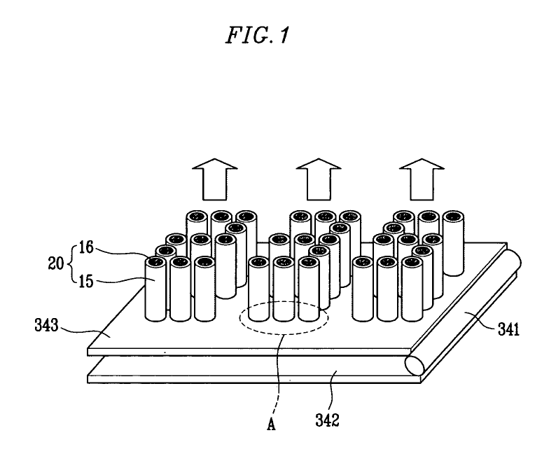

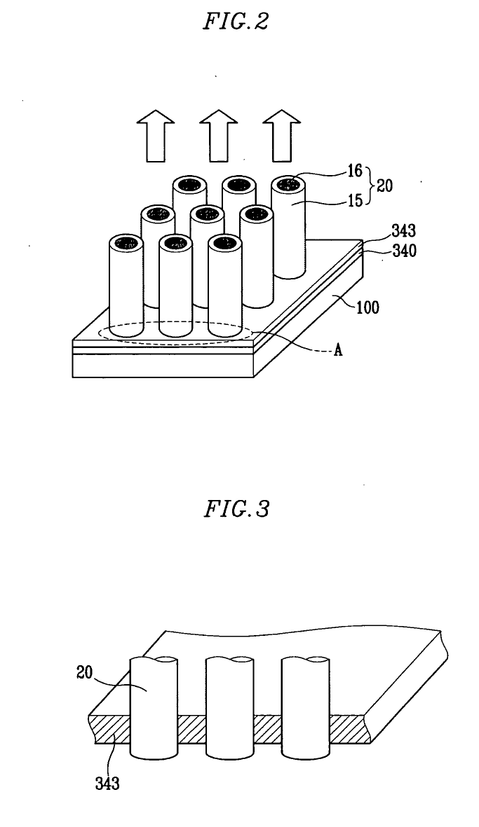

Referring to FIG. 1 to FIG. 3, a display device according to an exemplary embodiment of the present invention will be illustrated in detail. FIG. 1 is a schematic diagram of a display device according to an exemplary embodiment of the present invention, FIG. 2 is a schematic diagram of a display device according to another exemplary embodiment of the present invention, and FIG. 3 is an enlarged view of an ‘A’ portion of the display device shown in FIG. 1 and FIG. 2. Referring now to FIG. 1, a display device according to an exemplary embodiment of the present invention includes a light source 341, a reflector 342 disposed under the light source 341 and configured to reflect light, a substrate 343 disposed over the light source 341, and a plurality of nano-emitting bodies 20.

Since organic emitting bodies may have bandgaps similar to the energy of ultraviolet rays (UV), the light source 341 may have an ultraviolet ray providing lamp (UV-lamp). Alternatively, the light source 341 may have a cold cathode fluorescent lamp (CCFL), a light emitting diode (LED), or a fibrillar light source. The light source 341 may be an edge type in which the light source is disposed on one side, or a direct type in which a plurality of light sources are disposed in parallel. The reflector 342 is disposed under the light source 341, and reflects the light emitted from the light source 341 to the entire surface. The reflector 342 may be made of an opaque metal, such as aluminum (Al) or silver (Ag). The substrate 343 may be made of an opaque material, and acts as a light guide plate for uniformly transferring the light emitted from the light source 341 to the entire surface. A plurality of nano-emitting bodies 20 are formed on the substrate 343. The nano-emitting bodies 20 may be vertically raised or horizontally laid on the substrate 343.

As shown in FIG. 3, one side of each nano-emitting body 20 is inserted in the substrate 343. For example, the nano-emitting body 20 may be disposed on the substrate 343 such that a portion of the nano-emitting body 20 passes through the substrate 343. Thus, the light emitting from the light source 341 is emitted only through a nano-emitting body 20, so the light, having energy similar to that of ultraviolet rays and possibly considered harmful to humans, is not transmitted to the other regions. The nano-emitting body 20 may be formed at a predetermined or desired location depending on a particular number, character, symbol, configuration, or diagram to be displayed. A single bundle of nano-emitting bodies or a plurality of bundles of nano-emitting bodies, both referred to as nano-emitting body 20, may be formed. The nano-emitting body 20 is a linear emitting element having a diameter of about 200 nm or less, and includes an organic semiconductor that absorbs light such as ultraviolet rays, and that emits light such as visible rays.

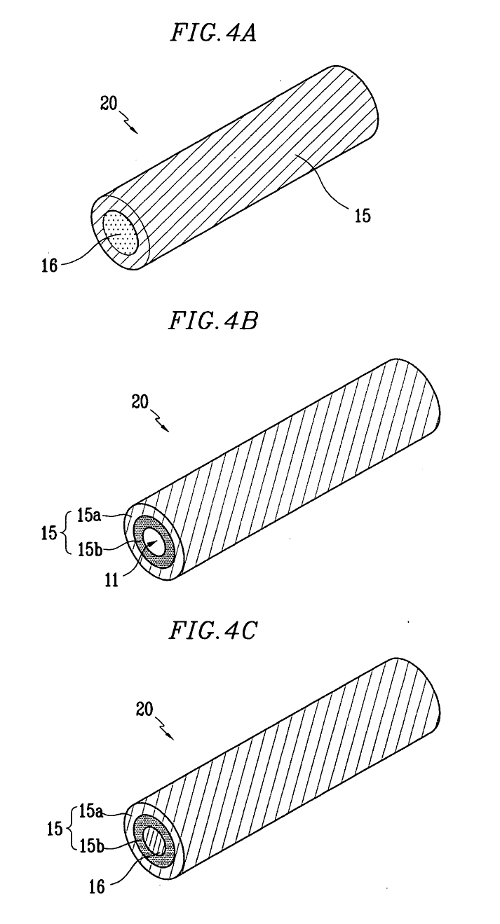

FIG. 4A to FIG. 4C are schematic diagrams showing many different types of nano-emitting bodies 20. The nano-emitting body 20 shown in FIG. 4A has a core 16 and a shell 15 surrounding the core 16. The shell 15 may surround only a central portion of the core 16, and both ends of the core 16 may be exposed. The core 16 is made of a luminescent organic semiconductor, and the shell 15 is made of a light transmission material that outputs the light emitted from the organic semiconductor to the outside. The luminescent organic semiconductor absorbs the light emitted from a light source and enters an excited state. When the excited state is changed to a ground state, the absorbed energy is emitted as light. The luminescent organic semiconductor may include either a low molecular weight material or a high molecular weight material. The low molecular weight material includes, for example, a metal complex such as tris-(8-hydroxyquinoline)-aluminum (Alq3) and bis-(benzoquinoline)-beryllium (BeBq2), or an organic compound such as rhodamine-B, fluorescein, pyrene, 4,4′-bis-(2,2′-diphenylethen-1-yl)-diphenyl (DPVBi), pentacene, and rubrene. Alternatively, the low molecular weight material may have a dopant at about 1% to 5% to increase emission efficiency. The high molecular weight material includes, for example, polypyrrole, polyaniline, or polythiophene. As further examples, there are also polyphenylenevinylene, poly[2-methoxy-5-(2-ethyl-hexyloxy)-1,4-phenylenevinylene], polyalkylthiophene, and polyvinylcarbazole. The light transmission material may be an insulating material, such as polymethylmethacrylate, polystyrene, polydivinylbenzene, polyacrylonitrile, and polycarbonate. The nano-emitting body 20 shown in FIG. 4B includes a first shell 15a of a tube type, a second shell 15b formed inside the first shell 15a and being a small tube type, and a hollow or pore 11 that is empty inside the second shell 15b. The first shell 15a may be made of a light transmission material, and the second shell 15b may be made of a luminescent organic semiconductor.

The nano-emitting body 20 shown in FIG. 4C has a first shell 15a of a tube type, a second shell 15b formed inside the first shell 15a and being a small tube type, and a core 16 formed inside the second shell 15b. The second shell 15b may be made of an organic semiconductor, and any one of the first shell 15a and the core 16 may be made of a light transmission material. Since the second shell 15b made of the organic semiconductor is disposed between the first shell 15a and the core 16, the organic semiconductor is physically or mechanically fixed and a nano-emitting body 20 having stable and high luminance is obtained. The nano-emitting bodies 20 shown in FIG. 4A and FIG. 4C are nanowires, while the nano-emitting body 20 shown in FIG. 4B is a nanotube.

A display device displays images by disposing the nano-emitting body 20 depending on a desired number, character, configuration, or diagram to be represented. The nano-emitting body 20 may include a luminescent organic semiconductor emitting different colors, and thus different colors may be represented. When the display device, as shown in FIG. 1, represents, for example, numbers ‘2’, ‘3’, ‘5’, the nano-emitting body 20 for representing a number ‘2’ includes a red luminescent organic semiconductor, the nano-emitting body 20 for representing a number ‘3’ includes a green luminescent organic semiconductor, and the nano-emitting body 20 for representing a number ‘5’ includes a blue luminescent organic semiconductor. Thus, different numbers or characters may be represented with different colors. When a display device includes emitting bodies emitting multiple colors, emitting colors may be changed by changing a wavelength of light.

FIG. 2 shows a modification of the display device shown in FIG. 1. A plurality of light sources (not shown) are disposed at the all surface, and the light sources are connected to the switching element (not shown) of each pixel. The switching element may be, for example, a thin film transistor (TFT). Referring to FIG. 2, a light source part 340 on which a plurality of light sources (not shown) are disposed is formed on a thin film transistor array panel 100. A substrate 343 is disposed on the light source part 340. The substrate 343 is made of an opaque material and a plurality of nano-emitting bodies 20 are inserted in the substrate 343. The thin film transistor array panel 100 includes a plurality of pixels, and a thin film transistor (not shown) is formed for each pixel. The light source part 340 includes a plurality of light sources (not shown) each corresponding to a pixel, and each of the light sources is respectively turned on or off by each thin film transistor. A single bundle or two or more bundles of the nano-emitting bodies 20 may form a single pixel. The nano-emitting bodies 20 disposed for each pixel are emitted or not emitted by the light source, which is turned-on and off in response to the thin film transistor for each pixel. Because a single or multiple bundles of the nano-emitting bodies 20 may be used for a single pixel, and the nano-emitting bodies 20 are individually turned on and off by the switching element, selective emission is provided for each pixel.

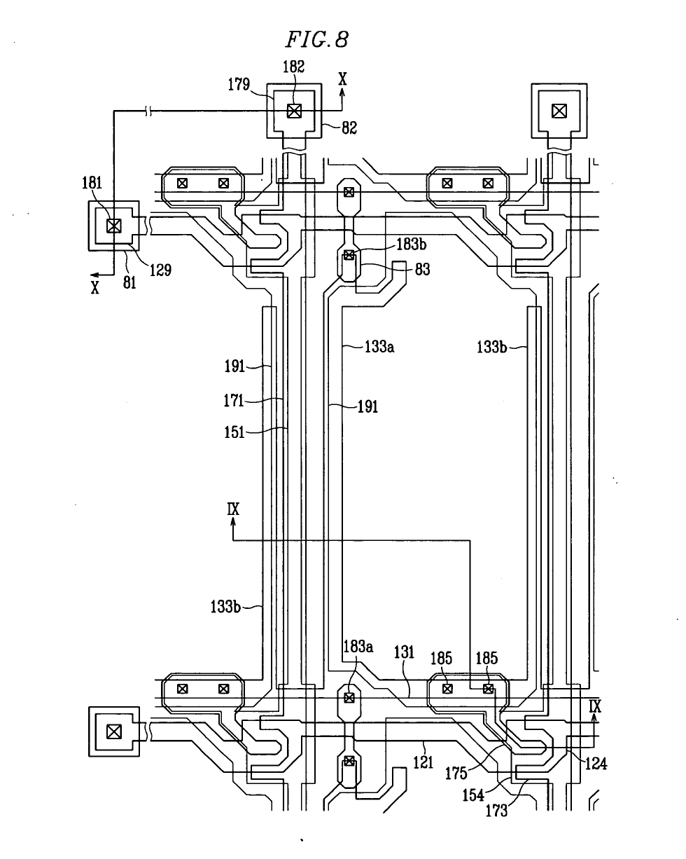

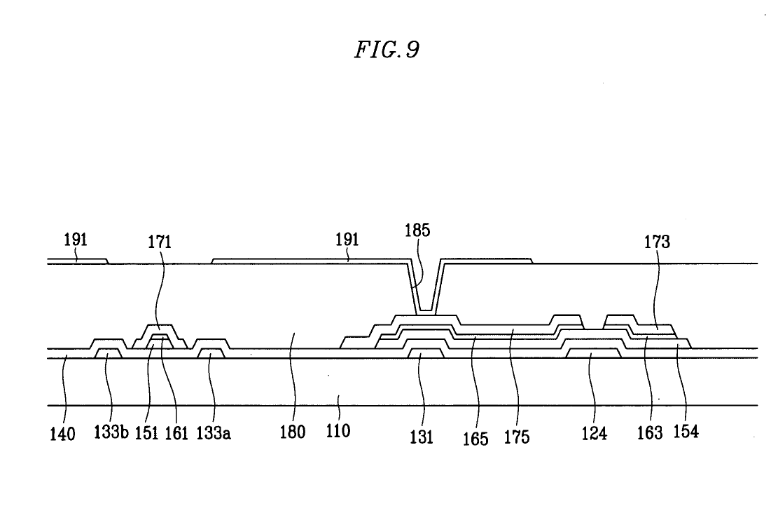

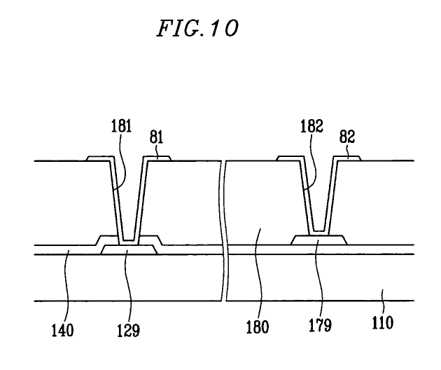

Referring to FIG. 6 to FIG.10, the thin film transistor array panel 100 of the display device shown in FIG. 2 is illustrated in detail. FIG. 6 and FIG. 7 are schematic diagrams of a thin film transistor array panel having a plurality of pixels Ps, respectively. FIG. 8 is a layout view of an enlarged pixel of the thin film transistor array panel shown in FIG. 6 and FIG. 7, and FIG. 9 and FIG. 10 are cross-sectional views of the thin film transistor array panel shown in FIG. 8, taken along lines IX-IX and X-X, respectively. As shown in FIG. 6 and FIG. 7, a thin film transistor array panel 100 includes a plurality of pixels P, each defined by a gate line 121 and a data line 171. A display area D is formed by the plurality of pixels P. One end of the gate lines 121 and data lines 171 pass over the display area D and extend to a peripheral area in order to receive an external signal. A switching element, that is, a thin film transistor 320, is formed on the plurality of pixels P. The thin film transistor 320 turns an image signal on and off in response to a scanning signal.

Referring to FIG. 8 to FIG. 10, a single pixel P is illustrated in detail. A plurality of gate lines 121 and a plurality of storage electrode lines 131 are formed on an insulating substrate 110 formed of transparent glass or plastic. The gate lines 121 transmit gate signals and extend in a horizontal direction. Each gate line 121 includes a plurality of gate electrodes 124 protruding downwardly, and a wide end portion 129 for making contact with another layer or an external driving circuit. A gate driving circuit (not shown) for generating the gate signals may be installed or positioned on a flexible printed circuit film (not shown) attached on the substrate 110, may be directly installed on the substrate, or may be integrated onto the substrate 110. When the gate driving circuit is directly integrated in the substrate 110, the gate lines 121 may extend and connect to the gate driving circuit directly.

A storage electrode line 131 receives a predetermined or effective voltage, and includes a stem extending substantially in parallel to the gate line 121 and a plurality of pairs of storage electrodes 133a and 133b branched from the stem. The storage electrode line 131 is disposed between two adjacent gate lines 121. The stem is close to a lower gate line of the two adjacent gate lines. Each of the storage electrodes 133a and 133b includes a fixed end connected to the stem and a free end opposite to the fixed end. The fixed end of the storage electrode 133a has an enlarged area, and the free end of the storage electrode 133a is bifurcated into a straight portion and a curved portion. The storage electrode line 131 may have different shapes and arrangements.

The gate line 121 and the storage electrode line 131 may be made of an aluminum containing metal such as aluminum (Al) or an aluminum alloy, a silver containing metal such as silver (Ag) or a silver alloy, a copper containing metal such as copper (Cu) or a copper alloy, a molybdenum containing metal such as molybdenum (Mo) or a molybdenum alloy, chromium (Cr), nickel (Ni), tantalum (Ta), or titanium (Ti). Alternatively, the gate line 121 and the storage electrode line 131 may have a multilayered structure composed of two conductive layers (not shown) of which physical properties are different from each other. One conductive layer may be made of a low resistivity metal to reduce signal delay or voltage drop, such as an aluminum containing metal, a silver containing metal, or a copper containing metal. The other conductive layer may be made of a material having excellent physical, chemical, or electrical contact characteristics with respect to a different material, for example indium tin oxide (ITO) or indium zinc oxide (IZO) including a molybdenum containing metal, chromium, tantalum, and titanium. Exemplary combinations of the two conductive layers include a combination of a chromium lower layer and an aluminum (alloy) upper layer, and a combination of an aluminum (alloy) lower layer and a molybdenum (alloy) upper layer. The gate lines 121 and the storage electrode lines 131 may be made of many other metals or conductors. In this disclosure, the term exemplary or the phrase exemplary embodiment denotes merely an example and not an ideal configuration or embodiment.

The side surfaces of the gate line 121 and storage electrode line 131 are inclined with respect to the surface of the substrate 110, and the inclined angle may be about 30° to about 80°. A gate insulating layer 140 of silicon nitride (SiNx) or silicon oxide (SiOx) is formed on the gate lines 121 and the storage electrode lines 131. A plurality of semiconductor stripes 151 are formed on the gate insulating layer 140, the semiconductor stripes 151 being formed of hydrogenated amorphous silicon (where amorphous silicon is abbreviated as a-Si) or polysilicon. Each semiconductor stripe 151 extends in a vertical direction and includes a plurality of projections 154 that protrude toward a gate electrode 124. The width of the semiconductor stripes 151 is enlarged around the gate lines 121 and the storage electrode lines 131, and they cover the gate lines 121 and the storage electrode lines 131.

A plurality of ohmic contact stripes and islands 161 and 165 are formed on the semiconductor stripes 151. The ohmic contacts 161 and 165 may be made of materials such as n+hydrogenated amorphous silicon on which an n-type impurity such as phosphorus (P) is highly doped, or silicide. The ohmic contact stripe 161 includes a plurality of protruding portions 163. The protruding portions 163 and the ohmic contact islands 165 form a pair and are disposed on the projections 154 of the semiconductor stripes 151. The side surfaces of the semiconductor stripes 151 and ohmic contacts 161 and 165 are inclined with respect to the surface of the substrate 110, and the inclined angle is about 30° to 80°.

A plurality of data lines 171 and a plurality of drain electrodes 175 are formed on the ohmic contacts 161 and 165 and the gate insulating layer 140. The data lines 171 transmit data voltages or signals and extend in a vertical direction, while intersecting the gate lines 121. Each of the data lines 171 intersects the storage electrode lines 131 and is formed between adjacent sets of the storage electrodes 133a and 133b. Each data line 171 has a plurality of source electrodes 173 extending toward the gate electrodes 124, and a wide end portion 179 for making contact with another layer or an external driving circuit. A data driving circuit (not shown) for generating the data voltages may be installed or positioned on a flexible printed circuit film (not shown) attached to the substrate 110, may be directly installed on the substrate, or may be integrated onto the substrate 110. In the case that the data driving circuit is directly integrated in the substrate 110, the data lines 171 may extend and connect to the data driving circuit.

The drain electrodes 175 are separated from the data lines 171 and face the source electrodes 173 on the projections 154 of the semiconductor stripes 151 between them. Each drain electrode 175 has a wide end portion and a narrow end portion. The wide end portion overlaps with the storage electrode line 131. The narrow end portion is partially surrounded with the U-shaped curved source electrode 173. One gate electrode 124, one source electrode 173, and one drain electrode 175, along with the projection 154 of the semiconductor stripe 151, form one thin film transistor (TFT). The thin film transistor has a channel formed in the projection 154 between the source electrode 173 and the drain electrode 175. The data line 171 and the drain electrode 175 may be made of a refractory metal, such as silver, copper, molybdenum, chromium, nickel, cobalt, tantalum, or titanium, or an alloy thereof. The data line 171 and the drain electrode 175 may have a multilayered structure having a refractory metal layer (not shown) and a low resistance conductive layer (not shown). As exemplary multilayered structures, there are a double layer having a chromium or molybdenum (alloy) lower layer and an aluminum (alloy) upper layer, and a triple layer having a molybdenum (alloy) lower layer, an aluminum (alloy) middle layer, and a molybdenum (alloy) upper layer.

The data lines 171 and the drain electrodes 175 may be made of many other metals or conductors. The side surfaces of the data line 171 and drain electrode 175 may be inclined with respect to the surface of the substrate 110, and the inclined angle may be about 30° to 80°. The ohmic contacts 161 and 165 are disposed only between the semiconductor stripes 151 disposed under the ohmic contacts 161 and 165 and the data lines 171 and drain electrodes 175 disposed above the ohmic contacts 161 and 165, and reduce contact resistance between them. Although the width of the semiconductor stripe 151 is narrower than the width of the data line 171 for the most part, the semiconductor stripe 151 is enlarged at a portion contacting the gate line 121 so that a profile of the semiconductor stripe 151 is smooth, thereby preventing the data line 171 from being shorted. Each projection 154 of semiconductor stripe 151 has exposed portions, for example, an exposed portion between the source electrode 173 and the drain electrode 175, or an exposed portion that is not covered by the data line 171 and the drain electrode 175.

A passivation layer 180 is formed on the data lines 171, the drain electrodes 175, and the exposed projections 154 of the semiconductor stripes 151. The passivation layer 180 may be made of an inorganic insulating material such as silicon nitride or silicon oxide, an organic insulating material, or a low dielectric material. The organic insulating material or the low dielectric material has a dielectric constant of 4.0 or less. Exemplary low dielectric materials include a-Si:C:O and a-Si:O:F that are formed by plasma enhanced chemical vapor deposition (PECVD). The passivation layer may be made of an organic insulating material having photosensitivity, and the surface of the passivation layer 180 may be even. Alternatively, the passivation layer 180 may have a double-layered structure having a lower inorganic layer and an upper organic layer in order to maintain the excellent insulating characteristic of an organic layer and to prevent the exposed semiconductor stripe 151 from being damaged. A plurality of contact holes 182 and 185 for exposing the end portions 179 of the data lines 171 and the drain electrodes 175, respectively, are formed in the passivation layer 180. A plurality of contact holes 181 for exposing the end portions 129 of the gate lines 121 and a plurality of contact holes 183a and 183b for exposing a portion of the storage electrode lines 131 around the fixed end of the storage electrodes 133a are formed in the passivation layer 180 and the gate insulating layer 140.

A plurality of conductors 191, a plurality of overpasses 83, and a plurality of contact assists 81 and 82 are formed on the passivation layer 180. The conductors 191, the overpasses 83, and the contact assists 81 and 82 may be made of a transparent conductive material such as ITO or IZO, or a reflective material such as aluminum, silver, chromium, and alloys thereof. The conductors 191 are physically and electrically connected to the drain electrodes 175 through the contact holes 185, and receive a data voltage from the drain electrodes 175. The other end of the conductors 191 is connected to a light source (not shown) to turn the light source on and off. The contact assists 81 and 82 are connected to the end portions 129 of the gate lines 121 and the end portions 179 of the data lines 171 through the contact holes 181 and 182, respectively. The contact assists 81 and 82 enhance and protect the connection between the end portions 179 and 129 of the data lines 171 and gate lines 121 and an external device. The overpasses 83 cross over the gate lines 121 and are connected to the exposed portions of the storage electrode lines 131 and the exposed portions of the free ends of the storage electrodes 133a through the contact holes 183a and 183b, which are disposed at the opposite side with the gate lines 121 between them. The storage electrodes 133a and 133b, the storage electrode lines 131, and the overpasses 83 may be used to repair defects of the gate lines 121, data lines 171, or thin film transistors.

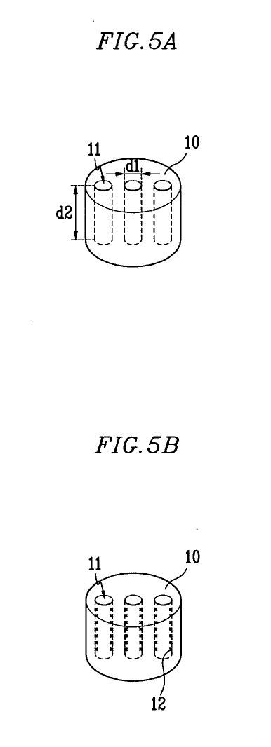

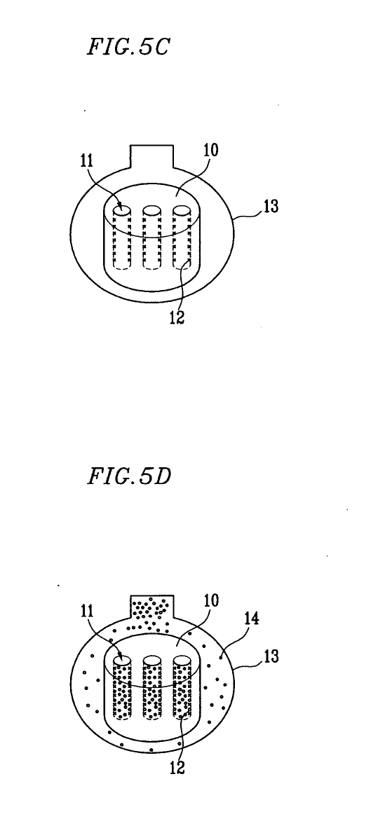

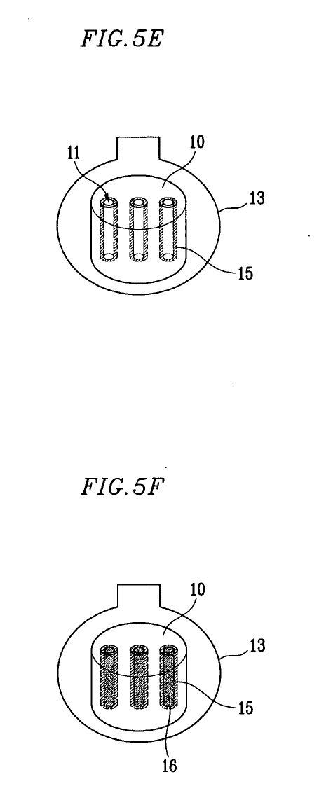

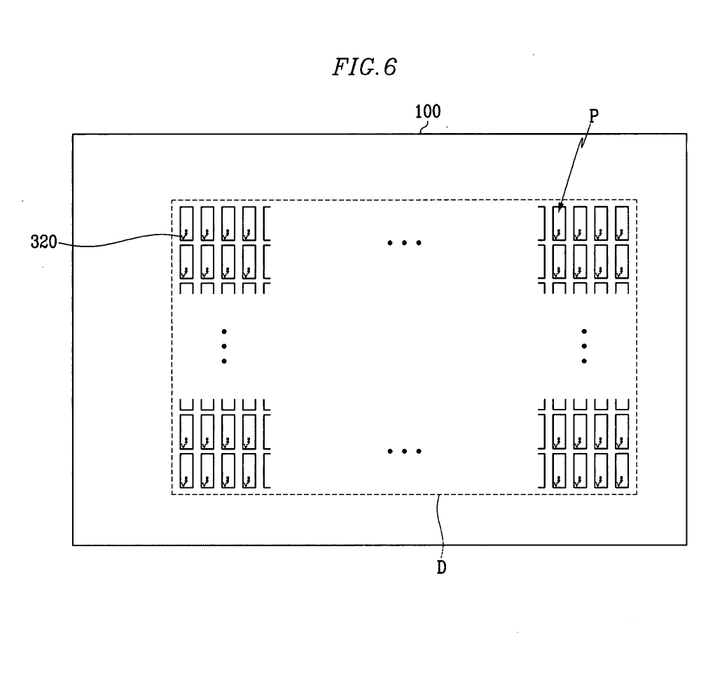

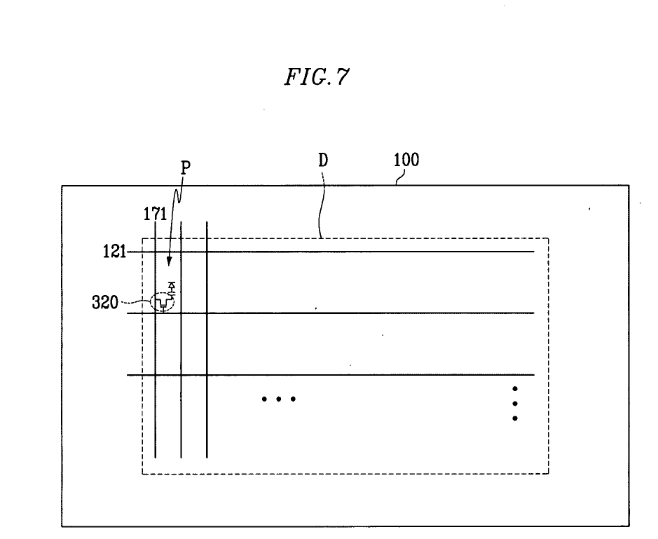

Referring to FIG. 5A to FIG. 5F, a method for manufacturing a nano-emitting body 20, according to an exemplary embodiment of the present invention, is illustrated in detail. FIG. 5A to FIG. 5F are schematic diagrams sequentially showing a method for manufacturing a nano-emitting body according to an exemplary embodiment of the present invention. As shown in FIG. 5A, a template 10 having a plurality of pores 11 is prepared. Each pore 11 may have a diameter d1 of about 200 nm or less, and a thickness d2 of several tens or several hundreds of μm. The template 10 is made of an anodic aluminum oxide membrane, but is not limited thereto. As shown in FIG. 5B, an initiator 12 is inserted in a pore 11. The initiator 12 initiates radical polymerization or redox polymerization. In a case that radical polymerization is performed, the initiator 12 may include 2,2′-azobisisobutyronitrile (AIBN), benzoyl peroxide (BPO), or cerium ammonium nitride (CAN). In a case that redox polymerization is performed, the initiator 12 may include ferric chloride (FeCl₃) or hydrogen peroxide. The initiator 12 is provided by soaking the template 10 in an initiator solution and drying the template 10, or by use of, or through, a vapor phase method, such as a vapor deposition or a vapor polymerization process. As shown in FIG. 5C, the template 10 is located in a vacuum chamber 13. The vacuum is, for example, about 10⁻² Torr or less. Monomers 14 are supplied to the vacuum chamber 13 by vapor, as shown in FIG. 5D. If the monomers 14 are liquid or solid at room temperature, the monomers 14 are vaporized, e.g., by applying vacuum or by heating. The monomers 14 may include, for example, methylmethacrylate, styrene, divinylbenzene, or vinylphenol. As shown in FIG. 5E, the monomers 14 are polymerized to form a shell 15 of a high molecular weight compound. The shell 15 is formed along the side wall of the pore 11. Thus, the shell 15 has a tube shape, and a smaller pore 11 is formed inside the shell i5. Polymerization is performed by heating the template 10 to a temperature of about 50° C. to about 200° C. depending on the type of monomers 14. The high molecular weight compound may include polymethylmethacrylate, polystyrene, polydivinylbenzene, or polyvinylphenol. As shown in FIG. 5F, a core 16 is formed in the pore 11.

The core 16, as described above, is formed by sequentially inserting the initiator 12 and the monomers 14 in the template 10 and performing polymerization. The monomers 14 may include pyrrole, aniline, or thiophene. Alternatively, the monomers 14 may be polymerized to form a polymer, such as polypyrrole, polyaniline, or polythiophene. As a result, a nano-emitting body 20 having the shell 15 and the core 16 is formed. Next, the nano-emitting body 20 is separated from the template 10. When the template 10 is made of aluminum oxide, the template 10 may be etched and removed with hydrochloric acid or sodium hydroxide. Alternatively, the template 10 having the nano-emitting body 20 formed in the pore 11 may be used. In this case, the separating process is unnecessary. In the above-described exemplary embodiment, the nano-emitting body 20 having a high molecular weight compound is formed by vapor polymerization. Alternatively, vapor deposition may be used in the case that at least one of the shell 15 and the core 16 has a low molecular weight compound. The low molecular weight compound may include, for example, pentacene or rubrene.

When a nano-emitting body 20 is formed by vapor polymerization or vapor deposition, no additional solvent is necessary unlike in a liquid method, and a collecting process is not required after a polymer is formed. The thickness of the nano-emitting body 20 is easily controlled depending on polymerization or deposition conditions, and thus a multiple nano-emitting body having a uniform surface and interface may be formed. In the exemplary embodiment of the present invention, a shell 15 is made of an organic insulating material and a core 16 is made of an organic semiconductor. Alternatively, the shell 15 may be made of an organic semiconductor and the core 16 may be made of an organic insulating material. In the exemplary embodiment of the present invention, a nano-emitting body 20 includes one shell 15 and one core 16. Alternatively, a nano-emitting body 20 may include two or more shells or it may have a tube shape having no core. The prepared nano-emitting body 20 is inserted in a substrate 343. The substrate 343 in which the nano-emitting body 20 is inserted is disposed on a thin film transistor array panel 100 and a light source part 340. As a result, a display device including a thin film transistor array panel 100, a light source part 340, a substrate 343, and a nano-emitting body 20 is manufactured as shown FIG. 2.

According to one or more exemplary embodiments of the present invention, since a display device includes a nano-emitting body, a micro sized pixel is formed. Thus, a display device having high resolution is provided. While this invention has been described in connection with what are considered to be practical, exemplary embodiments, it is to be understood that the invention is not limited to the disclosed embodiments, but, on the contrary, is intended to cover various modifications and equivalent arrangements included within the spirit and scope of the appended claims.

What is claimed is:

1. A display device, comprising:
a substrate;
at least one nano-emitting body disposed on the substrate, each nano-emitting body including at least one shell and having a coaxial structure;
at least one light source disposed on at least one of a lower and an upper part of the substrate and configured to provide the at least one nano-emitting body with light; and
at least one switching element disposed on the substrate and configured to turn the at least one light source on and off.

2. The device of claim 1, wherein a plurality of switching elements include a plurality of thin film transistors arranged on a pixel.

3. The device of claim 2, wherein a plurality of light sources are operatively connected to the plurality of thin film transistors.

4. The device of claim 1, wherein a plurality of switching elements are arranged in a matrix.

5. The device of claim 1, wherein the at least one nano-emitting body further comprises a luminescent organic semiconductor.

6. The device of claim 5, wherein the shell includes a light transmission material, the light transmission material comprising at least one of rhodamine-B, fluorescein, pyrene, pentacene, rubrene, polypyrrole, polyanihne, and polythiophene.

7. The device of claim 1, wherein at least one nano-emitting body further comprises a core and at least one shell surrounding the core.

8. The device of claim 7, wherein one of the core and the at least one shell comprises a luminescent organic semiconductor.

9. The device of claim 8, wherein the shell includes a light transmission material, the light transmission material comprising at least one of rhodamine-B, fluorescein, pyrene, pentacene, rubrene, polypyrrole, polyaniline, and polythiophene.

10. The device of claim 7, wherein at least one of the core and the at least one shell comprises a light transmission material.

11. The device of claim 10, wherein the light transmission material comprises an insulating material.

12. The device of claim 11, wherein the light transmission material comprises at least one of polymethylmethacrylate, polystyrene, polydivinylbenzene, polyacrylonitrile, and polycarbonate.

13. The device of claim 1, wherein the at least one nano-emitting body further comprises:
a first shell;
a core formed inside of the first shell; and
a second shell formed between the first shell and the core and having a luminescent organic semiconductor,
wherein at least one of the core and the first shell includes a light transmission material.

14. The device of claim 13, wherein the light transmission material comprises at least one of rhodamine-B, fluorescein, pyrene, pentacene, rubrene, polypyrrole, polyaniline, and polythiophene.

15. The device of claim 13, wherein the light transmission material comprises an insulating material.

16. The device of claim 15, wherein the light transmission material comprises at least one of polymethylnethacrylate, polystyrene, polydivinylbenzene, polyacrylonitrile, and polycarbonate.

17. The device of claim 1, wherein the at least one nano-emitting body comprises one of a nanowire and a nanotube.

18. The device of claim 1, wherein the at least one nano-emitting body includes the coaxial structure which is one of raised and laid.

19. The device of claim 1, wherein the nano-emitting body comprises the coaxial structure in which the nano-emitting body is one of raised and laid.

20. A method for manufacturing a display device comprising:
preparing at least one nano-emitting body;
disposing the prepared at least one nano-emitting body on a substrate; and
disposing at least one light source on one of a lower and an upper part of the substrate, the at least one light source being configured to provide the disposed at least one nano-emitting body with light.

21. The method of claim 20, wherein preparing the at least one nano-emitting body comprises:
preparing a template having a pore; and
supplying one of an organic and an inorganic material in the pore through a vapor phase method.

22. The method of claim 21, wherein supplying the one of an organic and an inorganic material comprises supplying the one of an organic and an inorganic material in the pore through vapor deposition.

23. The method of claim 21, wherein supplying the one of an organic and an inorganic material comprises supplying the one of an organic and an inorganic material in the pore through vapor polymerization.

24. The method of claim 23, wherein the vapor polymerization comprises:
supplying vapor monomers in the pore; and
polymerizing the supplied monomers.

25. The method of claim 24, wherein polymerizing the supplied monomers comprise polymerizing the monomers under vacuum.

26. The method of claim 24, wherein the monomers comprise at least one of methylmethacrylate, styrene, divinylbenzene, vinylphenol, pyrrole, aniline, thiophene, pentacene, and rubrene.

27. The method of claim 24, wherein the polymerization of the monomers is performed at a temperature of about 50° C. to about 200° C.

28. The method of claim 24, further comprising supplying polymerization initiators in the pore before supplying the monomers in the pore.

29. The method of claim 28, wherein the polymerization initiators comprise at least one of 2,2′-azobisisobutyronitrile (AIBN), benzoyl peroxide (BPO), cerium ammonium nitride (CAN), and FeCl₃.

30. The method of claim 24, further comprising separating at least one nano-emitting body from the template after polymerizing the monomers.

31. The method of claim 30, wherein the template comprises aluminum oxide, and separating the at least one nano-emitting body comprises etching the template.

32. The method of claim 31, wherein etching the template is performed using at least one of hydrochloric acid and sodium hydroxide.

33. The method of claim 20, wherein preparing the at least one nano-emitting body comprises:
preparing a template having a pore;
inserting a first material in the pore and forming a first shell of a tube shape having a hollowed inside; and
inserting a second material in the pore and forming a core inside the first shell.

34. The method of claim 33, wherein preparing the at least one nano-emitting body further comprises inserting a third material in the pore and forming a second shell having a tube shape inside the first shell, after forming the first shell.

35. The method of claim 34, wherein at least one of the first shell, the second shell, and the core is formed by one of vapor deposition and vapor polymerization.

36. The method of claim 34, wherein at least one of the first material, the second material, and the third material includes a luminescent organic semiconductor.
